(19) United States
(12) Patent Application Publication
(10) Pub. No.: US 2025/0316552 A1
(43) Pub. Date: Oct. 9, 2025

(54) ELECTRONIC COMPONENT AND MANUFACTURING METHOD THEREOF

(71) Applicant: Taiwan Semiconductor Manufacturing Company, Ltd., Hsinchu (TW)

(72) Inventors: Chen-Hsuan Tsai, Taitung City (TW); Chung-Ming Weng, Taichung City (TW); Tsai-Tsung Tsai, Taoyuan City (TW); Chin-Chuan Chang, Hsinchu County (TW); Ying-Ching Shih, Hsinchu City (TW); An-Jhih Su, Taoyuan City (TW)

(73) Assignee: Taiwan Semiconductor Manufacturing Company, Ltd., Hsinchu (TW)

(21) Appl. No.: 18/629,966

(22) Filed: Apr. 9, 2024

(51) Int. Cl. H01L 23/367; H01L 21/48; H01L 23/00; H01L 23/31

(52) U.S. Cl. CPC H01L 23/367; H01L 21/4846; H01L 23/3121; H01L 24/19; H01L 24/20; H01L 24/32; H01L 24/83; H01L 2224/19; H01L 2224/211; H01L 2224/32237; H01L 2224/83193; H01L 2924/1433; H01L 2924/1436; H01L 2924/1437

(57) ABSTRACT

An electronic component including a first circuit structure and a chip is provided. The first circuit structure has a recess. The chip is disposed on the first circuit structure and embedded in the recess. The first circuit structure comprises a conductive layer. A portion of the conductive layer forms a portion of a heat dissipation path partially located or exposed in the recess. The chip is thermally coupled to the heat dissipation path.

### BACKGROUND

The semiconductor integrated circuit (IC) industry has experienced a fast-paced growth. Technological advances in IC materials and design have produced generations of ICs where each generation has smaller and more complex circuits than the previous generation. The heat generated when the IC is operating may affect the quality. The quality or thickness of the IC may be improved through structural adjustments.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1J illustrate various cross-sectional views of some embodiments of a method of forming an electronic component.

FIGS. 1K and 1L illustrate a portion of various bottom views of some embodiments of an electronic component.

FIG. 2 illustrates a various cross-sectional view of some embodiments of an electronic component.

FIG. 3 illustrates a various cross-sectional view of some embodiments of an electronic component.

FIG. 4 illustrates a various cross-sectional view of some embodiments of an electronic component.

FIG. 5 illustrates a various cross-sectional view of some embodiments of an electronic component.

FIG. 6 illustrates a flow diagram of some embodiments of a method of forming an electronic component.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

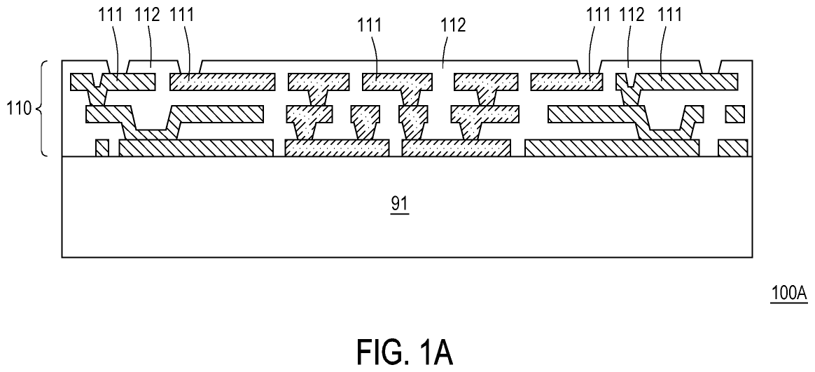

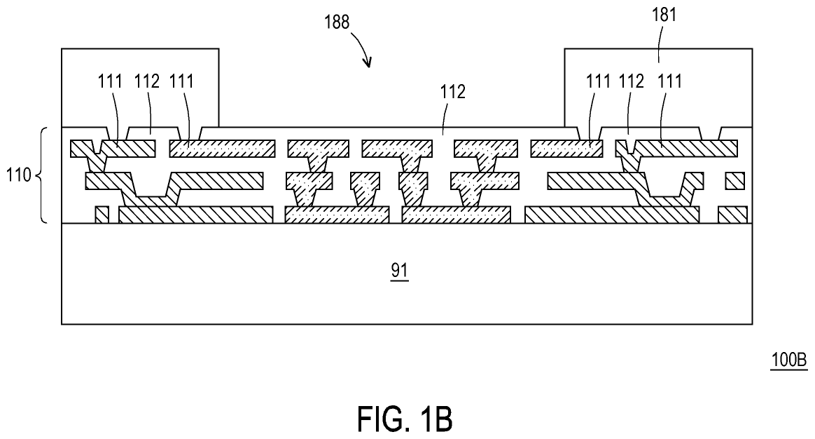

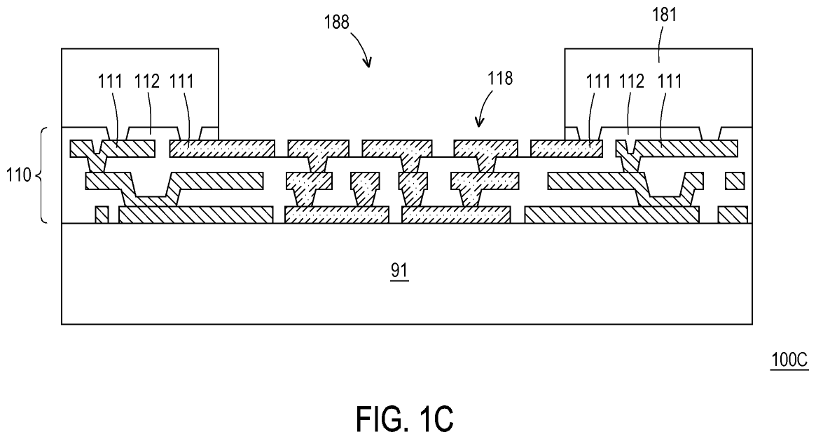

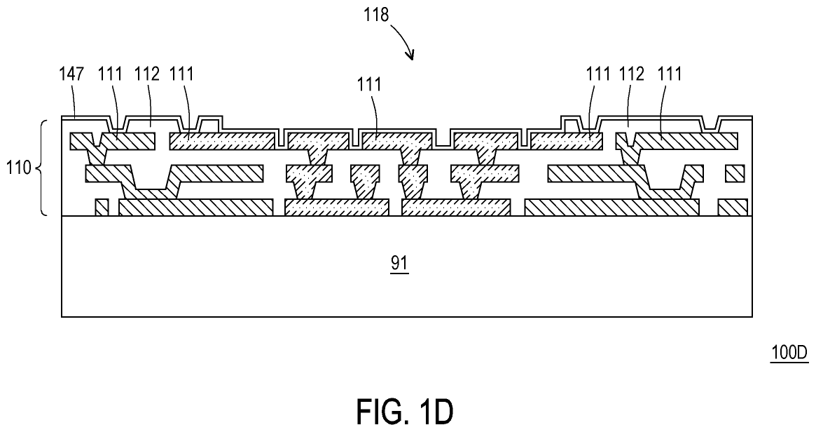

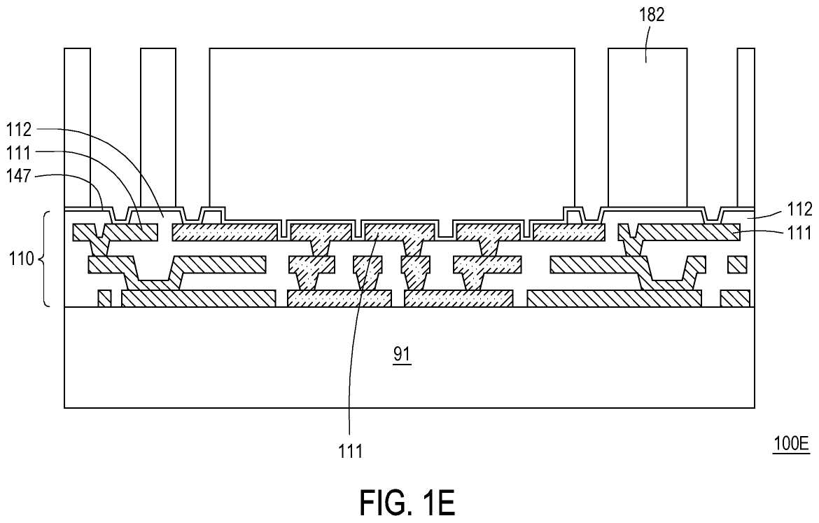

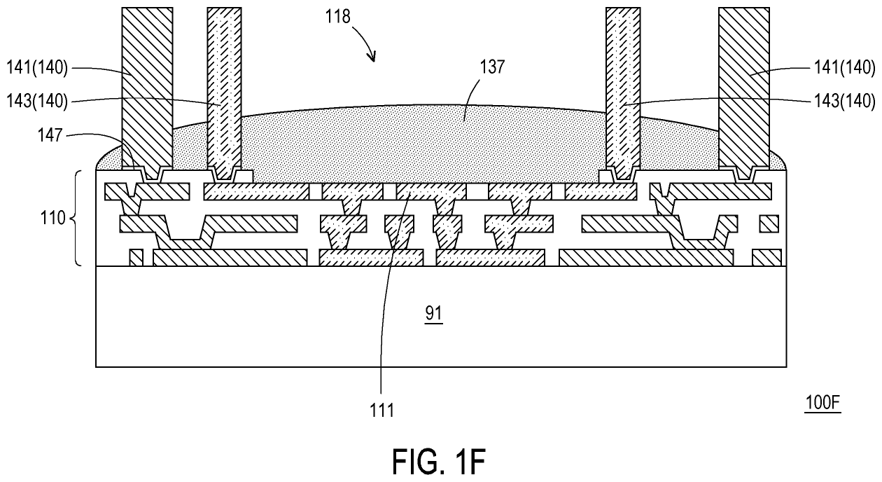

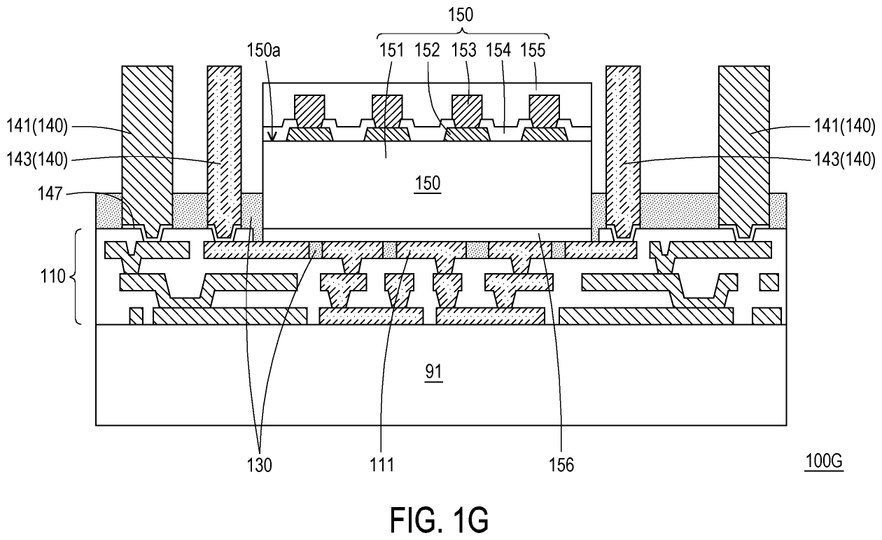

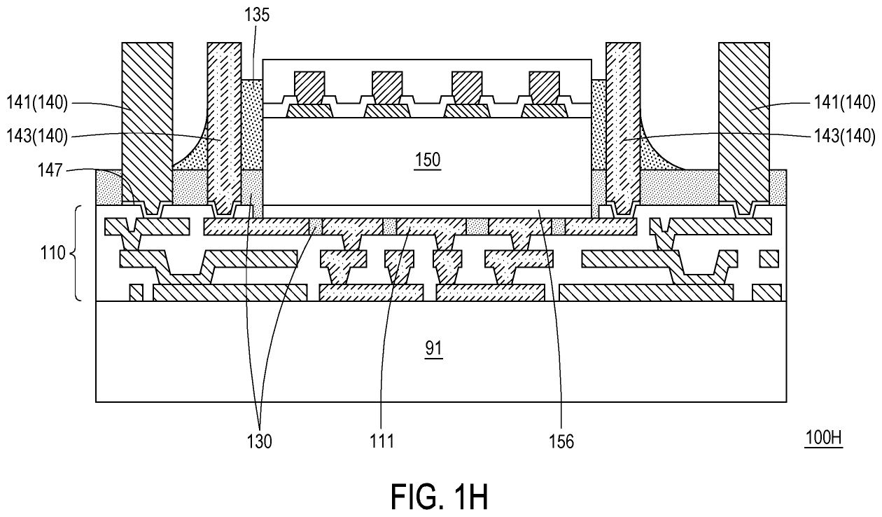

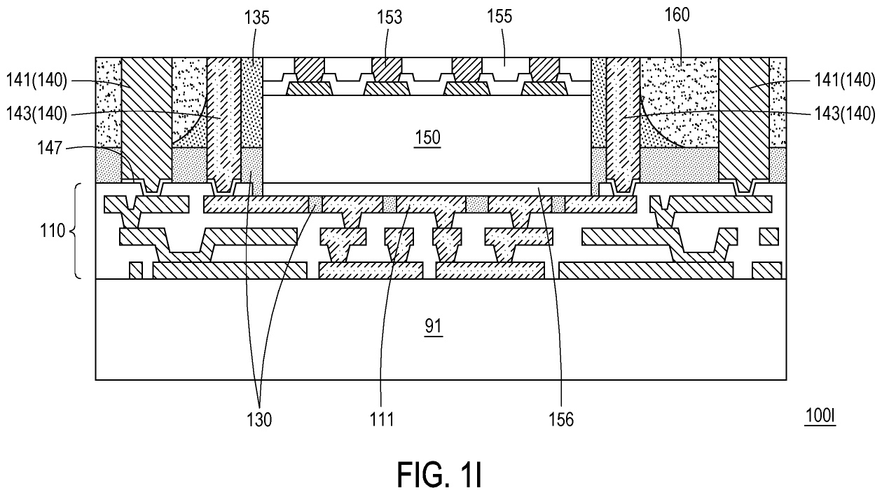

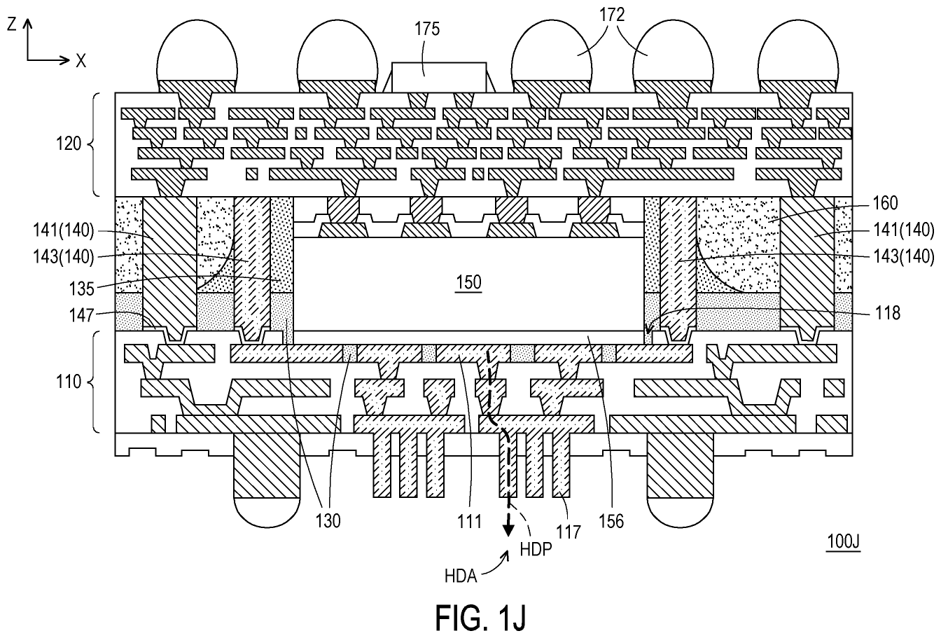

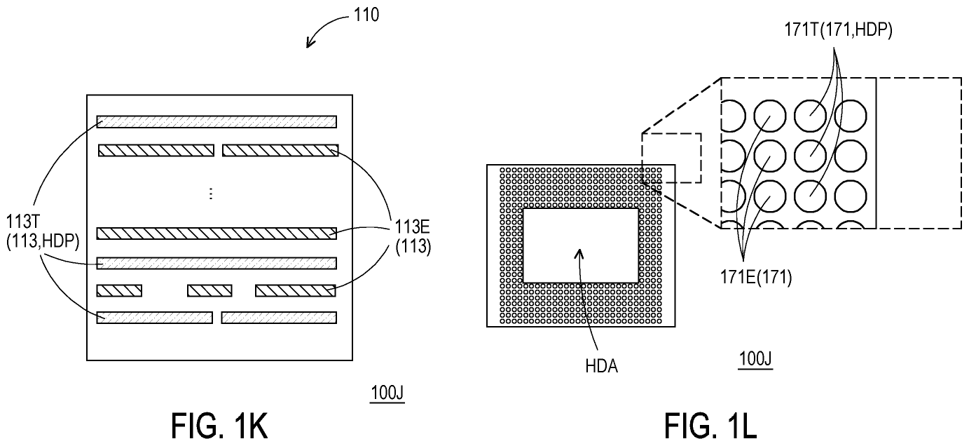

FIGS. 1A-1I illustrate various cross-sectional views of some embodiments of a method of forming an electronic component.

As shown in cross-sectional view of FIG. 1A, a structure 100A including a first circuit structure 110 is provided. The first circuit structure 110 may be formed by an appropriate process, for example, a deposition process (e.g., physical vapor deposition (PVD), chemical vapor deposition (CVD), atomic layer deposition (ALD), or the like) and/or a removal process (e.g., a photolithography followed by an etching process). In an embodiment, the first circuit structure 110 is referred as a redistribution layer (RDL) structure.

The first circuit structure 110 may be disposed on a carrier 91. The carrier 91 may include a semiconductor substrate (e.g., a silicon (Si) substrate or a semiconductor wafer), or a glass substrate, and the disclosure is not limited thereto. In an embodiment, a subsequent process by using a wafer for the carrier 91 is referred as a wafer-level packaging (WLP) process. In an embodiment, a subsequent process by using a panel (e.g., a glass panel) for the carrier 91 is referred as a panel-level packaging (PLP) process. However, the disclosure has no special limitation on the carrier 91, as long as the carrier 91 is suitable for supporting the structure formed thereon or a device disposed thereon.

The first circuit structure 110 includes one or more conductive layers and one or more insulating layers. For simplicity and/or clarity in the drawings, in FIG. 1A or other similar drawings, a corresponding boxed region including oblique lines in a circuit structure (e.g., the first circuit structure 110) may be a corresponding conductive layer, and/or a corresponding blank boxed region in the circuit structure (e.g., the first circuit structure 110) may be a corresponding insulating layer.

A pattern of the conductive layer is not limited in the disclosure. A portion of the conductive layer may be formed a corresponding circuit. A layout design of the circuit may be adjusted according to actual needs, and is not limited in the disclosure. For example, a portion of the topmost conductive layer (e.g., the conductive layer farthest from the carrier 91 as shown in FIG. 1A) 111 may include a contact pad or a landing pad. An appropriate conductor may be formed on or disposed on the contact pad or the landing pad. In an embodiment, the topmost insulating layer (e.g., the insulating layer farthest from the carrier 91 as shown in FIG. 1A) 112 is disposed on the topmost conductive layer 111 and having an appropriate opening to expose a portion of the topmost conductive layer 111 (e.g., the contact pad or the landing pad), but the disclosure is not limited thereto.

As shown in cross-sectional view of FIG. 1B, a structure 100B including a mask layer 181 is formed. The mask layer 181 is disposed on the topmost insulating layer 112 and having at least one opening 188 to expose a portion of the topmost insulating layer 112. The mask layer 181 may be formed by an appropriate process (e.g., a coating process, a photolithography or curing process, and a removal process). A material of the mask layer 181 is different from a material of the topmost insulating layer 188. In an embodiment, the material of the mask layer 181 includes photoresist (PR), but the disclosure is not limited thereto. In an embodiment, the mask layer 181 is referred as a hard-mask (HM) layer.

As shown in cross-sectional view of FIG. 1C, a structure 100C including a first circuit structure 110 having a recess 118 exposed a portion of the topmost conductive layer 111 is formed. For example, as shown in FIGS. 1B to 1C, a first removal process is performed on the structure 100B as shown in FIG. 1B to remove a portion of the insulating layer (e.g., a portion of the topmost insulating layer 112) for forming the recess 118 corresponding to the opening 188. As such, a portion of the topmost conductive layer 111 corresponding to the opening 188 is exposed.

In an embodiment, the aforementioned first removal process includes a dry etching process, for example, a reactive-ion etching (RIE) process, but the disclosure is not limited thereto.

In an embodiment, a depth of recess 118 is about 1 micrometer (μm)˜30 μm, for example, about 3 μm˜30 μm. In an embodiment, the depth of recess 118 corresponds a thickness of the portion of the remaining topmost insulating layer 112 disposed on the topmost conductive layer 111.

As shown in cross-sectional view of FIG. 1D, a structure 100D including a conductive layer 147 is formed. In an embodiment, after the portion of the topmost conductive layer 111 being exposed, a second removal process is performed to remove the mask layer 181 (as shown in FIG. 1C) for forming a structure similar to the structure 100D. Then, the conductive layer 147 is formed after the mask layer 181 being removed.

In an embodiment, the aforementioned second removal process includes a photoresist strip (PR strip) process, but the disclosure is not limited thereto. In an embodiment, the conductive layer 147 may conformally cover the remaining topmost insulating layer 112 and a portion of the topmost conductive layer 111 exposed thereby of the first circuit structure 110. The conductive layer 147 may be formed by an appropriate process (e.g., a sputtering process). In an embodiment, the conductive layer 147 is referred as a seed layer.

As shown in cross-sectional view of FIG. 1E, a structure 100E including a mask layer 182 is formed. The mask layer 182 is disposed on the topmost insulating layer and embedded in the recess 118 (as labelled in FIGS. 1C and/or 1D). The mask layer 182 has at least one opening corresponding to a portion of the topmost conductive layer 111 (e.g., the contact pad or the landing pad).

In an embodiment, a material and/or a forming process of the mask layer 182 may be the same as or similar to the material and/or the forming process the aforementioned mask layer 181. In an embodiment, the mask layer 182 is a preform layer, for example, a dry film having the corresponding opening.

As shown in cross-sectional view of FIG. 1F, a structure 100F including at least one conductor 140 is formed. For example, a conductive material may fill in the opening of the mask layer 182 by an appropriate process (e.g., a plating process). Then, a removal process (e.g., a dry film stripping process) is performed to remove the mask layer 182 (as shown in FIG. 1B) for forming a least one conductive feature corresponding to the opening. Then, the aforementioned conductive feature is referred as a mask, a removal process (e.g., an etching process) is performed to remove the portion of the conductive layer 147 non-overlapped to the conductive feature. During the aforementioned removal process, a portion of the conductive feature may be slightly removed. As such, the conductor 140 including the aforementioned conductive feature and a corresponding portion of the remaining conductive layer 147 thereunderneath is formed. In an embodiment, the conductor 140 is referred as a conductive pillar. Additionally, for clarity, the corresponding portion of the remaining conductive layer 147 underneath the conductive feature is omitted in subsequent drawings.

As shown in FIG. 1F, after the conductor 140 being formed, an adhesion material 137 is optionally formed at least filling in the recess 118.

As shown in cross-sectional view of FIG. 1G, a structure 100G including at least one chip 150 is formed. The chip 150 may include a substrate 151, a plurality of connection pads 152 and a plurality of chip connection pieces 153. A device region (not illustrated) is provided on one side of the substrate 151, and a surface on which the device region is located may be referred to as an active surface 150a. The connection pads 152 may be disposed on the active surface 150a. The chip connection pieces 153 may be disposed on the connection pads 152.

A device in the device region (e.g., devices in the device region of the chip 150) may be formed using front-end of line (FEOL) fabrication techniques. The device may include an active device (e.g., a transistor), a passive device (e.g., a resistor, a capacitor, or an inductance), or an integrated device thereof. Examples of semiconductor devices include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. In an general chip design, the device in the device region (e.g., devices in the device region of the chip 150) may be electrically connected to a corresponding connection pad (e.g., one or more connection pads 152 of the chip 150) and a corresponding chip connection piece (e.g., one or more connection pieces 153 of the chip 150) through a corresponding back end of line interconnect (BEOL Interconnect) which may be formed using back-end of line (BEOL) fabrication techniques.

The connection pad 152 is, for example, an aluminum pad or a copper pad, but the disclosure is not limited thereto. The connection pads 152 may be partially covered by an insulation layer 154, and the insulation layer 154 may expose a portion of the connection pad 152. A passivation layer 155 may cover the insulation layer 154, and the passivation layer 155 may expose a portion of the connection pad 152.

In an embodiment, the chip connection piece 153 is formed by a lithography process, a sputtering process, an electroplating process and/or an etching process, but the disclosure is not limited thereto. For example, the chip connection piece 153 may include a seed layer and a plating layer disposed thereon, but the disclosure is not limited thereto. In an embodiment, a chip connection piece 153 includes a pre-formed conductive piece. For example, the chip connection piece may include a pre-formed conductive pillar, but the disclosure is not limited thereto.

In an embodiment, the chip 150 includes a memory chip (e.g., a dynamic random access memory (DRAM) chip, a static random access memory (SRAM) chip or a high bandwidth memory (HBM) chip), an application-specific integrated circuit (ASIC) chip, an application processor (AP) chip, a system on chip (SoC) chip or a high performance computing (HPC) chip, but the disclosure is not limited thereto.

The chip 150 is thermally coupled to a portion of the conductive layer (e.g., the portion of the topmost conductive layer 111) exposed in the recess 118 (as labelled in FIGS. 1C and/or 1D). For example, the chip 150 (e.g., the substrate 151 of the chip 150) in contact with the portion of the topmost conductive layer 111 exposed in the recess 118. For example, an insulating thermal interface material (TIM) 156 is disposed between the chip 150 and a portion of the conductive layer exposed in the recess 118, and the insulating thermal interface material 156 in contact with the portion of the conductive layer (e.g., the portion of the topmost conductive layer 111) exposed in the recess 118 and the chip 150 (e.g., the substrate 151 of the chip 150). In an embodiment, the insulating thermal interface material 156 disposed on the backside of the chip 150 (e.g., the backside of the substrate 151 of the chip 150) is referred as a portion of the chip.

In an embodiment, since the adhesion material (e.g., the adhesion material 137 as shown in FIG. 1F) is still flowable during the chip 150 being configured, a portion of the uncured adhesion material is disposed between the chip 150 and the first circuit structure 110. Additionally, since the chip 150 is disposed before the adhesion material is cured, and then the adhesion material is full-cured to form an insulating adhesion layer 130 (may be referred as a first adhesion layer) after the chip 150 is configured, the chip 150 and the first circuit structure 110 are well-fixed to each other through the formed the insulating adhesion layer 130. That is, a portion of the adhesion layer 130 is disposed between the chip 150 and the first circuit structure 110, and/or a portion of the adhesion layer 130 laterally cover a side wall of a portion of the topmost conductive layer 111 of the first circuit structure 110. In an embodiment, a portion of the insulating adhesion layer 130 further laterally cover a portion of the conductor 140 (e.g., a lower portion of the conductor 140).

As shown in cross-sectional view of FIG. 1H, a structure 100H including a filling layer 135 is optionally formed. The filling layer 135 may be by an appropriate process (e.g., a dispensing and curing process). For example, a filling glue is dispensed on the first circuit structure 110 to laterally cover a portion of chip 150 and a portion of the conductor 140. Then, the filling glue disposed on the first circuit structure 110 is cured for forming an insulating filling layer (e.g., the filling layer 135).

In an embodiment, a material of the filling glue includes a polymer and a thermally conductive material. The aforementioned thermally conductive material includes particles having high thermal conductivity and good electrical isolation, for example, SiN, AlN, silicon carbide (SiC), diamond, a suitable insulating 2D material (e.g., hexagonal boron nitride (h-BN, graphitic BN)), or a mixture thereof. The filling layer 135 in contact with the chip 150 and a portion of the conductor 140. As such, heat (e.g., thermal energy) may be transferred from the chip 150 to the conductor 140 through the filling layer 135 quickly or efficiently. That is, the heat generated may be transferred to the conductor 140 easily and quickly when the chip 150 is operating.

In an embodiment, the material of the adhesion layer 130 is similar to that of the filling layer 135, but the difference is that the adhesion layer 130 has higher adhesion. That is, heat (e.g., thermal energy) may also be transferred from the chip 150 to the conductor 140 through the adhesion layer 130 quickly or efficiently.

As shown in cross-sectional view of FIG. 1I, a structure 100I including an encapsulant 160 is formed.

A process of forming an insulating encapsulant (e.g., the encapsulant 160) is exemplified as follows. An encapsulating material covering the chip 150 and the conductor 140 is formed. The encapsulating material is a molten molding compound (e.g., epoxy) formed on the first circuit structure 110 by, for example, a molding process or other suitable methods. Then, the molten molding compound is cooled and cured. The chip 150 and/or the conductor 140 may not be exposed to the cured encapsulating material, but the invention is not limited thereto. Then, after the encapsulating material is cured, a reducing process (e.g., a polishing process) may be performed to remove a portion of the cured encapsulating material, so as to form the encapsulant 160 laterally covering the chip 150 and the conductor 140 and to expose the chip connection pieces 153 of the chip 150 and a portion of the conductor 140. In an embodiment, after performing the aforementioned reducing process, a top surface of the chip connection piece 153, a top surface of the conductor 140 and an encapsulating top surface of the encapsulant 160 are substantially coplanar.

As shown in cross-sectional view of FIG. 1J, a structure 100J including a second circuit structure 120 is provided. A forming process of the second circuit structure 120 may be the same as or similar to the forming process of the first circuit structure 110. In an embodiment, the second circuit structure 120 is referred as a redistribution layer (RDL) structure. The second circuit structure 120 includes one or more conductive layers and one or more insulating layers. For simplicity and/or clarity in the drawings, in FIG. 1J or other similar drawings, a corresponding boxed region including oblique lines in a circuit structure (e.g., the second circuit structure 120) may be a corresponding conductive layer, and/or a corresponding blank boxed region in the circuit structure (e.g., the second circuit structure 120) may be a corresponding insulating layer.

A portion of the conductive layer may be formed a corresponding circuit. A layout design of the circuit may be adjusted according to actual needs, and is not limited in the disclosure. For example, a corresponding circuit of the second circuit structure 120 is electrically connected to a corresponding conductor 140 (e.g., the conductor 141). For example, a corresponding circuit of the second circuit structure 120 is electrically connected to a corresponding device of the chip 150.

In an embodiment, an appropriate object is formed or configured on the second circuit structure 120. The object formed or configured on the second circuit structure 120 may be electrically connected to a corresponding circuit of the second circuit structure 120.

For example, a conductive terminal is formed or configured on the second circuit structure 120. The conductive terminal 172 may be a conductive pillar, a solder ball, a conductive bump, or a conductive terminal having other forms or shapes. The conductive terminal 172 may be formed through deposition, electroplating, ball placement, reflow, and/or other suitable processes.

For example, a device 175 is formed or configured on the second circuit structure 120. The device 175 includes a passive device (e.g., a multi-layer ceramic capacitor (MLCC)), an antenna, or an electromagnetic interference shielding (EMI shielding) element, but the invention is not limited thereto.

In an embodiment, an appropriate object is formed or configured on the first circuit structure 110 after removing the carrier 91. The object formed or configured on the first circuit structure 110 may be electrically connected to a corresponding circuit of the first circuit structure 110 or thermally coupled to a corresponding heat dissipation path of the first circuit structure 110.

For example, a conductive terminal 171 is formed or configured on the first circuit structure 110. The conductive terminal 171 may be a conductive pillar, a solder ball, a conductive bump, or a conductive terminal having other forms or shapes.

For example, a device (not shown) is formed or configured on the first circuit structure 110. The device includes a passive device (e.g., a multi-layer ceramic capacitor (MLCC)), an antenna, an electromagnetic interference shielding (EMI shielding) element, or a heat sink, but the invention is not limited thereto.

In an embodiment, a further process is performed on the outer surface (e.g., the bottommost surface) of the first circuit structure 110 for forming a heat dissipation pattern 117. For example, a portion of the bottommost insulating layer may be removed to expose a portion of a bottommost conductive layer for being the heat dissipation pattern 117. For example, a thermally conductive layer (e.g., a metal layer) may be formed on the bottommost insulating layer and/or the bottommost conductive layer for being the heat dissipation pattern 117. In an embodiment, the heat dissipation pattern 117 is referred as a portion of the first circuit structure 110 structurally.

In an embodiment, a dicing process is performed after forming the second circuit structure 120. A side wall of the second circuit structure 120, a side wall of the encapsulant 160, and a side wall of the first circuit structure 110 (or further, and a side wall of the adhesion layer 130) may aligned and/or be forming a portion of a side wall of the whole structure 100J.

The structure 100J as shown in FIG. 1J may be a portion of an electronic component. That is, FIG. 1J may illustrate a portion cross-sectional view of some embodiments of an electronic component. FIGS. 1K and 1L may illustrate a portion of various bottom views of some embodiments of an electronic component. For example, FIG. 1K may correspond to a corresponding pattern of a conductive layer of a circuit structure. For example, FIG. 1K may correspond to a corresponding configuration pattern of conductive terminals of disposed on a circuit structure.

As shown in FIGS. 1J to 1L, the electronic component 100J may include a first circuit structure 110 and a chip 150. The chip 150 is disposed on the first circuit structure 110. The first circuit structure 110 has a recess 118 so that the chip 150 is embedded therein. As such, a total thickness of the electronic component 100J may be reduced.

The first circuit structure 110 includes one or more conductive layers. A portion of the conductive layer 111 forms a heat dissipation path HDP. A portion of the heat dissipation path HDP is located and/or exposed in the recess 118. The chip 150 is thermally coupled to the heat dissipation path HDP.

The portion of the conductive layer 111 for forming the heat dissipation path HDP may be a dummy pattern of the first circuit structure 110. It is noted that “dummy” herein may be referred to the dummy on the signal, but may have other uses. For example, during the process of forming the electronic component 100J, a dummy pattern may cause corresponding stress in a corresponding portion of the structure, thereby the process quality may be improved. For example, a portion of the dummy pattern may be electrically grounded, thereby the electromagnetic interference may be reduced.

The electronic component 100J may further include an adhesion layer 130. The adhesion layer 130 directly contacts the chip 150 and the first circuit structure 110, and further fills in the recess 118. In a direction (e.g., the z direction) parallel to the thickness of the electronic component 100J, a portion of the adhesion layer 130 is disposed between the chip 150 and the first circuit structure 110. In a direction (e.g., the x direction) perpendicular to the thickness of the electronic component 100J, a portion of the adhesion layer 130 laterally covers a side wall of the conductive layer 111 located and exposed in the recess 118.

A thermal conductivity of the adhesion layer 130 may be larger than a thermal conductivity of the insulating layer of the first circuit structure 110. For example, a material for forming the adhesion layer 130 may include particles having high thermal conductivity and good electrical isolation.

The electronic component 100J may further include a second circuit structure 120, an encapsulant 160, and at least one conductor 140. The chip 150, the conductor 140, the adhesion layer 130, and the encapsulant 160 are disposed between the first circuit structure 110 and a second circuit structure 120. The conductor 140 penetrates through the encapsulant 160. The conductor 140 may be referred as a through molding via (TMV). A corresponding circuit of the first circuit structure 110 is electrically connected to a corresponding circuit of the first circuit structure 110 through a corresponding conductor 140 (e.g., the conductor 141).

A certain conductor 140 (e.g., the conductor 142) is thermally coupled to the conductive layer 111 located and exposed in the recess 118. The conductor 142 forms a heat dissipation path HDP. For example, a heat dissipation path HDP includes the conductive layer 111 located and exposed in the recess 118 and the conductor 142 disposed thereon and thermally coupled thereto.

The conductor 142 for forming the heat dissipation path HDP may be a dummy conductor. It is noted that “dummy” herein may be referred to the dummy on the signal, but may have other uses. That is, a “dummy” structure does not participate in the transmission of signals. For example, during the process of forming the electronic component 100J, a dummy conductor may cause corresponding stress in a corresponding portion of the structure, thereby the process quality may be improved. For example, the dummy conductor may be electrically grounded, thereby the electromagnetic interference may be reduced. For example, the heat dissipation path HDP may be thermally coupled to a heat dispersion (e.g., the heat sink), thereby the heat dissipation efficiency may be improved.

The electronic component 100J may further include a filling layer 135. The filling layer 135 is disposed between the adhesion layer 130 and the second circuit structure 120. A thermal conductivity of the filling layer 135 may be larger than a thermal conductivity of the insulating layer of the first circuit structure 110 and/or a thermal conductivity of the insulating layer of the second circuit structure 120. For example, a material for forming the filling layer 135 may include particles having high thermal conductivity and good electrical isolation. The filling layer 135 directly contacts the chip 150 and the conductor 140 for forming the heat dissipation path HDP, thereby the heat dissipation efficiency may be improved.

An outer surface of the first circuit structure 110 may have a heat dissipation area HDA. A heat dissipation pattern 117 is located within the heat dissipation area HDA. The heat dissipation pattern 117 may be formed by a portion of the conductive layer of the first circuit structure 110 protruding from the inside to the outside. The heat dissipation pattern 117 is a portion of the heat dissipation path HDP and/or thermally coupled to the chip 150.

In an embodiment, the heat dissipation path HDP is a certain conductive routing of the first circuit structure 110. And the conductive routing being the heat dissipation path HDP extends from one side (e.g., an upper side) to another side (e.g., a lower side) of the first circuit structure 110.

The electronic component 100J may further include conductive terminals 171. A certain conductive terminal 171 (e.g., the conductive terminal 171T) is a portion of the heat dissipation path HDP. For example, a heat dissipation path HDP includes the conductive layer 111 located and exposed in the recess 118 and the conductor 140 disposed thereon and thermally coupled thereto. The conductive terminal 17T for forming the heat dissipation path HDP may be a dummy terminal. It is noted that “dummy” herein may be referred to the dummy on the signal, but may have other uses. For example, during the process of forming the electronic component 100J, a dummy terminal may cause corresponding stress in a corresponding portion of the structure, thereby the process quality may be improved. For example, a portion of the dummy terminal may be electrically grounded, thereby the electromagnetic interference may be reduced.

In the first circuit structure 110, for a same conductive layer 113, a portion 113T of the conductive layer 113 may be a portion of the heat dissipation path HDP, and a portion 113E of the conductive layer 113 may be a circuit for signal transmission. The portion 113T of the conductive layer 113 may be thermally coupled to at least one of the conductive terminal 171T and the chip 150. The portion 113E of the conductive layer 113 may be electrically coupled to at least one of the conductive terminal 171F and the chip 150 for signal transmission.

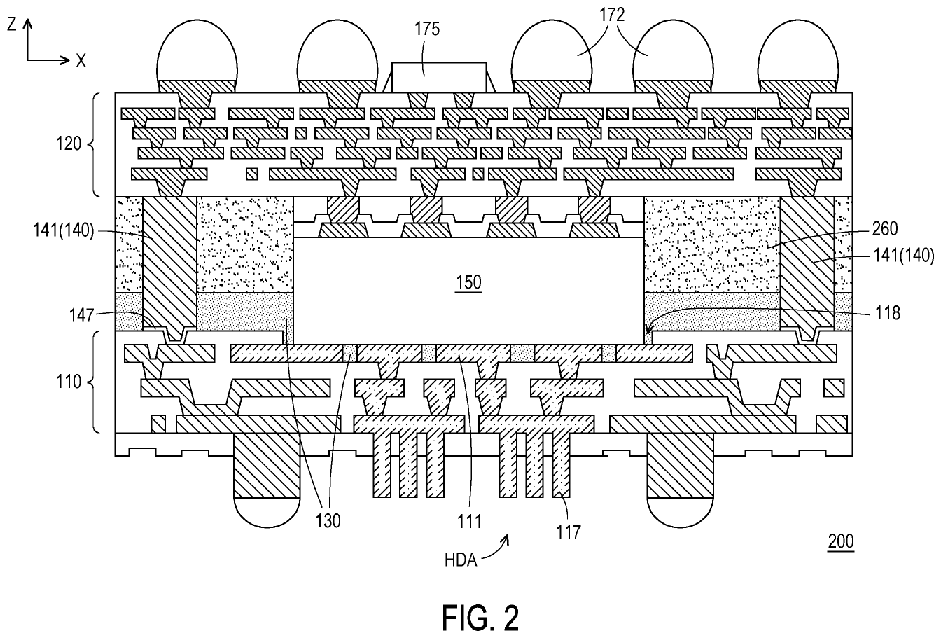

FIG. 2 illustrates a various cross-sectional view of some embodiments of an electronic component. Elements, devices, or components having same or similar functions may be denoted by same or similar referential numbers. Descriptions of said elements, devices, or components may be omitted for brevity.

The structure 200 as shown in FIG. 2 may be a portion of an electronic component. The structure 200 as shown in FIG. 2 may be similar to the structure 100J as shown in FIG. 1J. As shown in FIG. 2, the electronic component 200 may include a first circuit structure 110, a second circuit structure 120, a chip 150, an adhesion layer 130, an encapsulant 260, and at least one conductor 140. A material and/or a forming process of the encapsulant 260 may be the same as or similar to the material and/or the forming process of the aforementioned encapsulant 160. In an embodiment, the encapsulant 260 may further laterally cover the chip 150.

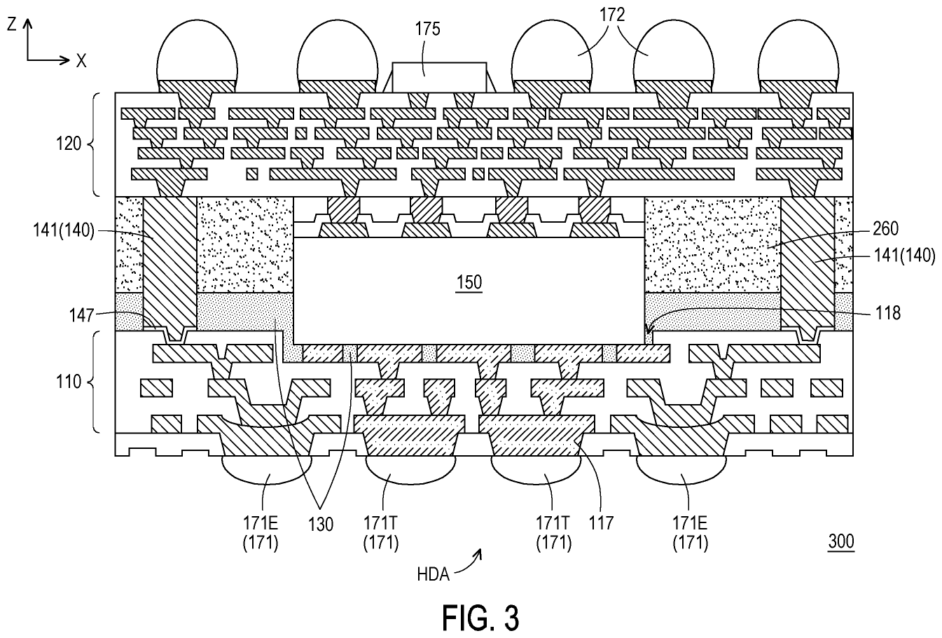

FIG. 3 illustrates a various cross-sectional view of some embodiments of an electronic component. Elements, devices, or components having same or similar functions may be denoted by same or similar referential numbers. Descriptions of said elements, devices, or components may be omitted for brevity.

The structure 300 as shown in FIG. 3 may be a portion of an electronic component. The structure 300 as shown in FIG. 3 may be similar to the structure 200 as shown in FIG. 2. As shown in FIG. 3, the electronic component 300 may include a first circuit structure 110, a second circuit structure 120, a chip 150, an adhesion layer 130, an encapsulant 160, at least one conductor 140, and conductive terminals 171. In an embodiment, a certain conductive terminal 171 (e.g., the conductive terminal 171T) is a portion of the heat dissipation path HDP. For example, the conductive terminal 171T is disposed on and/or thermally coupled to the heat dissipation pattern 117 is located within the heat dissipation area HDA.

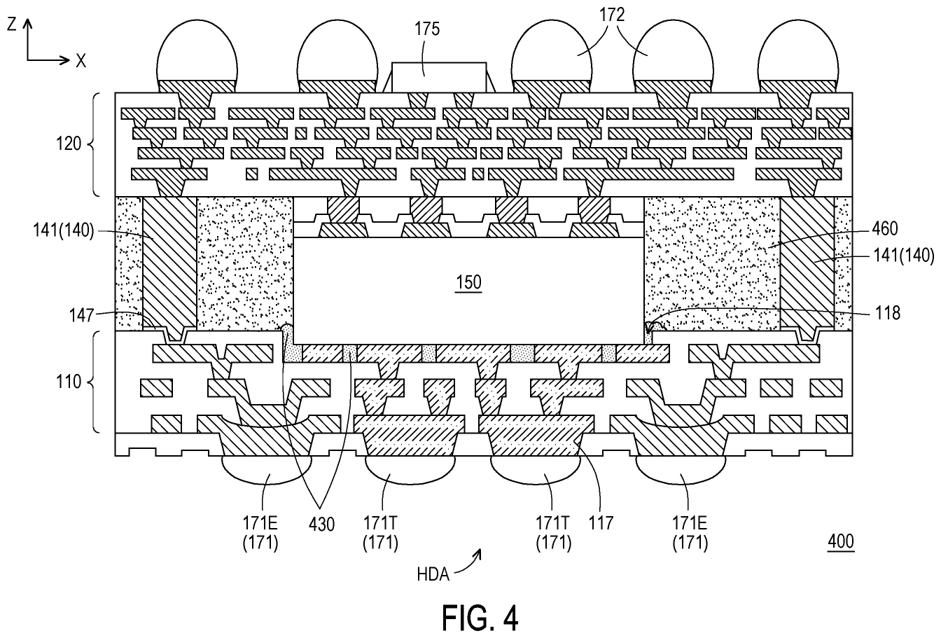

FIG. 4 illustrates a various cross-sectional view of some embodiments of an electronic component. Elements, devices, or components having same or similar functions may be denoted by same or similar referential numbers. Descriptions of said elements, devices, or components may be omitted for brevity.

The structure 400 as shown in FIG. 4 may be a portion of an electronic component. The structure 400 as shown in FIG. 4 may be similar to the structure 300 as shown in FIG. 3. As shown in FIG. 4, the electronic component 400 may include a first circuit structure 110, a second circuit structure 120, a chip 150, an adhesion layer 130, an encapsulant 160, and at least one conductor 140. A material and/or a forming process of the adhesion layer 430 and/or the encapsulant 460 may be the same as or similar to the material and/or the forming process of the aforementioned adhesion layer 130 and/or the aforementioned encapsulant 160. In an embodiment, the encapsulant 460 directly contacts the first circuit structure 110 and the second circuit structure 120.

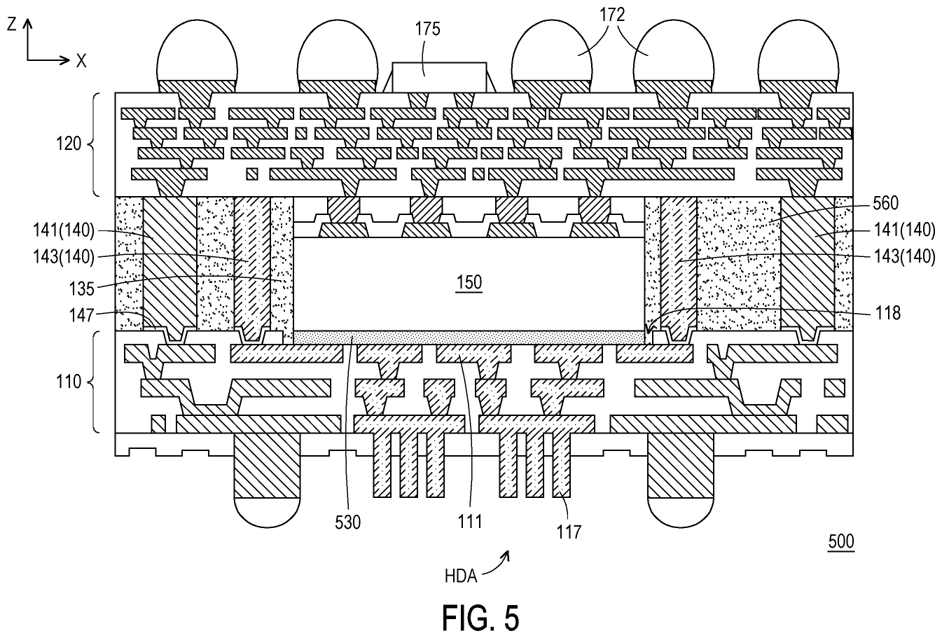

FIG. 5 illustrates a various cross-sectional view of some embodiments of an electronic component. Elements, devices, or components having same or similar functions may be denoted by same or similar referential numbers. Descriptions of said elements, devices, or components may be omitted for brevity.

The structure 500 as shown in FIG. 5 may be a portion of an electronic component. The structure 500 as shown in FIG. 5 may be similar to the structure 100J as shown in FIG. 1J. As shown in FIG. 5, the electronic component 500 may include a first circuit structure 110, a second circuit structure 120, a chip 150, an adhesion layer 530, an encapsulant 160, and at least one conductor 140. A material and/or a forming process of the encapsulant 560 may be the same as or similar to the material and/or the forming process of the aforementioned encapsulant 160. In an embodiment, the encapsulant 560 directly contacts the first circuit structure 110 and the second circuit structure 120.

A material of the adhesion layer 530 may be the same as or similar to the material of the aforementioned adhesion layer 130. The adhesion layer 530 may be formed by a lamination process. In an embodiment, the adhesion layer 530 is a thermal interface material film.

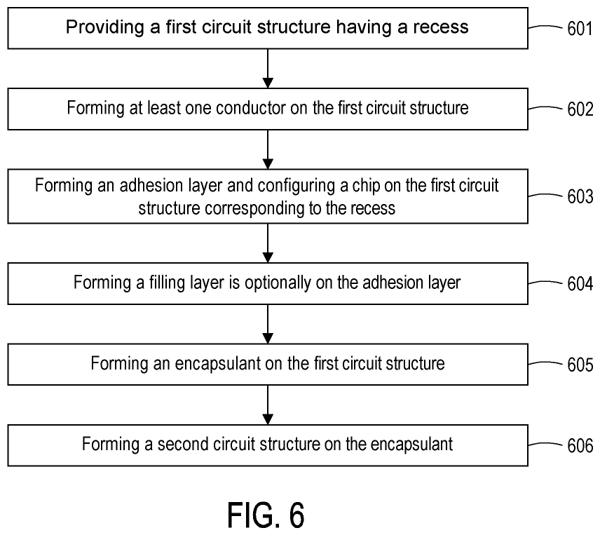

FIG. 6 illustrates a flow diagram of some embodiments of a method of forming an electronic component.

At act 501, a first circuit structure having a recess is provided. FIGS. 1A to 1C illustrate cross-sectional views corresponding to various embodiments of act 601.

At act 602, at least one conductor is formed on the first circuit structure. FIGS. 1D to 1F illustrate cross-sectional views corresponding to various embodiments of act 602.

At act 603, an adhesion layer is formed and a chip is configured on the first circuit structure and correspond to the recess. FIGS. 1F to 1G illustrate cross-sectional view corresponding to various embodiments of act 603.

At act 604, a filling layer is optionally formed on the adhesion layer. FIGS. 1H to 1I illustrate cross-sectional views corresponding to various embodiments of act 604.

At act 605, an encapsulant is formed on the first circuit structure. FIG. 1I illustrates a cross-sectional view corresponding to various embodiments of act 605.

At act 606, a second circuit structure is formed on the encapsulant. FIGS. 1J and 2-4 illustrate cross-sectional views corresponding to various embodiments of act 606.

Accordingly, in some embodiments, the present disclosure relates to an electronic component having a thinner thickness. Accordingly, in some embodiments, the present disclosure relates to an electronic component having a better heat dissipation. Accordingly, in some embodiments, the present disclosure relates to a manufacturing process of an electronic component. During the manufacturing process of an electronic component, the silicon substrate is not thinned and the warpage may be reduced.

In accordance with some embodiments of the present disclosure, an electronic component comprises a first circuit structure and a chip. The first circuit structure has a recess. The chip is disposed on the first circuit structure and embedded in the recess. The first circuit structure comprises a conductive layer. A portion of the conductive layer forms a portion of a heat dissipation path partially located or exposed in the recess. The chip is thermally coupled to the heat dissipation path. In an embodiment, the heat dissipation is a dummy pattern of the first circuit structure. In an embodiment, the electronic component further comprises a second circuit structure, an encapsulant, and at least one conductor. The chip, the conductor and the encapsulant are disposed between the first circuit structure and a second circuit structure. The conductor penetrates through the encapsulant for electrically connecting to the first circuit structure and the second circuit structure. In an embodiment, the electronic component further comprises an adhesion layer. The adhesion layer is filled in the recess and in contact with the chip and the first circuit structure. In an embodiment, a portion of the adhesion layer is disposed between the chip and the first circuit structure. In an embodiment, a portion of the adhesion layer laterally covers a side wall of the conductive layer located and exposed in the recess. In an embodiment, the electronic component further comprises a second circuit structure, an encapsulant, and at least one conductor. The chip, the conductor, the adhesion layer, and the encapsulant are disposed between the first circuit structure and a second circuit structure. The at least one conductor comprises a first conductor penetrates through the encapsulant for electrically connecting to the first circuit structure and the second circuit structure. In an embodiment, the first conductor further penetrates through the adhesion layer. In an embodiment, the at least one conductor further comprises a second conductor penetrates through the encapsulant and the adhesion layer to contact the conductive layer for being another portion of the heat dissipation path. In an embodiment, wherein the at least one conductor further comprises a second conductor penetrates through the encapsulant for being another portion of the heat dissipation path, and wherein the second conductor is a dummy conductor.

In accordance with some embodiments of the present disclosure, an electronic component comprises a first circuit structure, a second circuit structure, a chip, an encapsulant, and a first conductor. The chip has an active surface facing the second circuit structure. The chip is disposed between the first circuit structure and the second circuit structure. The encapsulant is disposed between the first circuit structure and the second circuit structure. The encapsulant laterally surrounds the chip. The first conductor penetrates through the encapsulant for electrically connecting to the first circuit structure and the second circuit structure. The electronic component has a heat dissipation path thermally coupled to the chip. A portion of a conductive layer of the first circuit structure forms a portion of the heat dissipation path. In an embodiment, the first circuit structure has a first side and a second side opposite the first side; and the portion of the conductive layer being the portion of the heat dissipation path continually extends from the first side to the second side of the first circuit structure. In an embodiment, the first circuit structure has a first side and a second side opposite the first side; and the portion of the conductive layer being the portion of the heat dissipation path protrudes on the first side or the second side. In an embodiment, the electronic component further comprises a second conductor. The second conductor penetrates through the encapsulant to contact the portion of the conductive layer of the first circuit structure for being another portion of the heat dissipation path. In an embodiment, the heat dissipation path is a dummy structure. In an embodiment, the first circuit structure has a recess for the chip to be embedded therein. In an embodiment, the electronic component further comprises a conductive terminal. The conductive terminal is disposed on the first circuit structure for being another portion of the heat dissipation path.

In accordance with some embodiments of the present disclosure, an electronic component comprises a first circuit structure and a chip. The first circuit structure comprises a topmost conductive layer. The chip is embedded in the first circuit structure to thermally couple to a portion of the topmost conductive layer of the first circuit structure. In an embodiment, the topmost conductive layer thermally coupled to the chip is a dummy pattern of the first circuit structure. In an embodiment, the electronic component further comprises a second circuit structure, an encapsulant, and at least one conductor. The chip, the conductor and the encapsulant are disposed between the first circuit structure and a second circuit structure. The conductor penetrates through the encapsulant for electrically connecting to the first circuit structure and the second circuit structure. In an embodiment, the electronic component further comprises an adhesion layer. The adhesion layer is at least filled on the first circuit structure and in contact with the chip. In an embodiment, a portion of the adhesion layer is disposed between the chip and the first circuit structure. In an embodiment, a portion of the adhesion layer laterally covers a side wall of the topmost conductive layer thermally coupled to the chip. In an embodiment, the electronic component further comprises a second circuit structure, an encapsulant, and at least one conductor. The chip, the conductor, the adhesion layer, and the encapsulant are disposed between the first circuit structure and a second circuit structure. The at least one conductor comprises a first conductor penetrates through the encapsulant for electrically connecting to the first circuit structure and the second circuit structure. In an embodiment, the first conductor further penetrates through the adhesion layer. In an embodiment, the at least one conductor further comprises a second conductor penetrates through the encapsulant and the adhesion layer to contact the topmost conductive layer for thermally coupling to the chip. In an embodiment, the at least one conductor further comprises a second conductor penetrates through the encapsulant for thermally coupling to the chip, and wherein the second conductor is a dummy conductor.

In accordance with some embodiments of the present disclosure, an electronic component comprises a first circuit structure, a second circuit structure, a chip, an encapsulant, and a first conductor. The first circuit structure comprises a conductive routing. The chip has an active surface facing the second circuit structure. The chip is disposed between the first circuit structure and the second circuit structure. The encapsulant is disposed between the first circuit structure and the second circuit structure, and laterally surrounding the chip. The first conductor penetrates through the encapsulant for electrically connecting to the first circuit structure and the second circuit structure. A portion of the conductive routing of the first circuit structure thermally coupled to the chip. In an embodiment, the first circuit structure has a first side and a second side opposite the first side; and the portion of the conductive routing thermally coupling to the chip continually extends from the first side to the second side of the first circuit structure. In an embodiment, the first circuit structure has a first side and a second side opposite the first side; and the portion of the conductive routing thermally coupling to the chip protrudes on the first side or the second side. In an embodiment, the electronic component further comprises a second conductor. The second conductor penetrates through the encapsulant to contact the portion of the conductive routing of the first circuit structure for thermally coupling to the chip. In an embodiment, the portion of the conductive routing of the first circuit structure thermally coupled to the chip is a dummy structure. In an embodiment, the chip is embedded in the first circuit structure. In an embodiment, the electronic component further comprises a conductive terminal. The conductive terminal is disposed on the first circuit structure for thermally coupling to the chip.

In accordance with some embodiments of the present disclosure, a method comprises: providing a first circuit structure having a recess; forming at least one conductor on the first circuit structure; forming an adhesion layer on the first circuit structure corresponding to the recess; configuring a chip on the first circuit structure corresponding to the recess; forming an encapsulant on the first circuit structure; and forming a second circuit structure on the encapsulant. In an embodiment, the method further comprises: forming a filling layer on the adhesion layer. In an embodiment, a removal process is performed to expose a portion of a conductive layer for forming the first circuit structure having the recess.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic component, comprising:
a first circuit structure, comprising a topmost conductive layer; and
a chip, embedded in the first circuit structure to thermally couple to a portion of the topmost conductive layer of the first circuit structure.

2. The electronic component of claim 1, wherein the topmost conductive layer thermally coupled to the chip is a dummy pattern of the first circuit structure.

3. The electronic component of claim 1, further comprising:
a second circuit structure;
an encapsulant; and
at least one conductor, wherein:
the chip, the conductor and the encapsulant are disposed between the first circuit structure and a second circuit structure; and
the conductor penetrates through the encapsulant for electrically connecting to the first circuit structure and the second circuit structure.

4. The electronic component of claim 1, further comprising:
an adhesion layer, at least filled on the first circuit structure and in contact with the chip.

5. The electronic component of claim 4, wherein a portion of the adhesion layer is disposed between the chip and the first circuit structure.

6. The electronic component of claim 4, wherein a portion of the adhesion layer laterally covers a side wall of the topmost conductive layer thermally coupled to the chip.

7. The electronic component of claim 4, further comprising:
a second circuit structure;
an encapsulant; and
at least one conductor, wherein:
the chip, the conductor, the adhesion layer, and the encapsulant are disposed between the first circuit structure and a second circuit structure; and
the at least one conductor comprises a first conductor penetrates through the encapsulant for electrically connecting to the first circuit structure and the second circuit structure.

8. The electronic component of claim 7, wherein the first conductor further penetrates through the adhesion layer.

9. The electronic component of claim 7, wherein the at least one conductor further comprises a second conductor penetrates through the encapsulant and the adhesion layer to contact the topmost conductive layer for thermally coupling to the chip.

10. The electronic component of claim 7, wherein the at least one conductor further comprises a second conductor penetrates through the encapsulant for thermally coupling to the chip, and wherein the second conductor is a dummy conductor.

11. An electronic component, comprising:
a first circuit structure, comprising a conductive routing;
a second circuit structure;
a chip, having an active surface facing the second circuit structure, and disposed between the first circuit structure and the second circuit structure;
an encapsulant, disposed between the first circuit structure and the second circuit structure, and laterally surrounding the chip; and
a first conductor, penetrating through the encapsulant for electrically connecting to the first circuit structure and the second circuit structure, wherein:
a portion of the conductive routing of the first circuit structure thermally coupled to the chip.

12. The electronic component of claim 11, wherein:
the first circuit structure has a first side and a second side opposite the first side; and
the portion of the conductive routing thermally coupling to the chip continually extends from the first side to the second side of the first circuit structure.

13. The electronic component of claim 11, wherein:
the first circuit structure has a first side and a second side opposite the first side; and
the portion of the conductive routing thermally coupling to the chip protrudes on the first side or the second side.

14. The electronic component of claim 11, further comprising:
a second conductor, penetrating through the encapsulant to contact the portion of the conductive routing of the first circuit structure for thermally coupling to the chip.

15. The electronic component of claim 11, wherein the portion of the conductive routing of the first circuit structure thermally coupled to the chip is a dummy structure.

16. The electronic component of claim 11, wherein the chip is embedded in the first circuit structure.

17. The electronic component of claim 11, further comprising:
a conductive terminal, disposed on the first circuit structure for thermally coupling to the chip.

18. A method, comprising:
providing a first circuit structure having a recess;
forming at least one conductor on the first circuit structure;
forming an adhesion layer on the first circuit structure corresponding to the recess;
configuring a chip on the first circuit structure corresponding to the recess;
forming an encapsulant on the first circuit structure; and
forming a second circuit structure on the encapsulant.

19. The method of claim 18, further comprising:
forming a filling layer on the adhesion layer.

20. The method of claim 18, wherein a removal process is performed to expose a portion of a conductive layer for forming the first circuit structure having the recess.
